(19) United States
(12) Patent Application Publication
(10) Pub. No.: US 2023/0214553 A1
(43) Pub. Date: Jul. 6, 2023

(54) SYSTEM AND METHOD FOR SENSOR POSITION OPTIMIZATION FOR AUTONOMOUS VEHICLES

(71) Applicant: QPIAI INDIA PRIVATE LIMITED, Bangalore (IN)

(72) Inventors: AMLAN MUKHERJEE, Durgapur (IN); Arun Sehrawat, Panipat (IN); Nagendra Nagaraja, Bangalore (IN); Aswanth Krishnan, Palakkad (IN); Nawaf Alampara, Palakkad (IN); Manjunath Venkatesh, Bangalore (IN); Lakshya Priyadarshi, Lucknow (IN)

(21) Appl. No.: 18/093,510

(22) Filed: Jan. 5, 2023

(30) Foreign Application Priority Data
Jan. 5, 2022 (IN) 202241000561

(51) Int. Cl. G06F 30/20; G06N 10/60; B62D 65/00

(52) U.S. Cl. CPC G06F 30/20; G06N 10/60; B62D 65/00; B60W 60/00

(57) ABSTRACT

The embodiments herein disclose a method and a system for sensor position optimization in an autonomous vehicle. The system and method is configured to receive the weight assigned for each point in the regions of interest around the autonomous vehicle, possible positions of the sensors on the vehicle, and field of view and price of each sensor. The method further calculates a field of view and price of each specification based on the received weights of points in the regions of interest and possible positions of the sensors on the vehicle. The method runs quantum or quantum-inspired variational algorithm for various sensor configurations and the system completes the total number of iterations to generate the final sensor configuration.

### CROSS-REFERENCE TO RELATED APPLICATIONS

The embodiments herein claims the priority of the Provisional Patent Application (PPA) with serial number IN 202241000561 and title “A SYSTEM AND METHOD FOR SENSOR POSITION OPTIMIZATION FOR AUTONOMOUS VEHICLES”, filed at Indian Patent Office on Jan. 05, 2022, and the contents of which are included entirely as reference herein.

### BACKGROUND

### Technical Field

The embodiment herein relates to field of automotive vehicles. Further, the embodiment herein, also relates to a system and a method of sensor positions optimization in an autonomous vehicle. Further, the embodiment herein also relates to the system and the method of sensor positions optimization in the autonomous vehicles based on quantum and quantum-inspired variational algorithms.

### Description of the Related Art

The construction of an autonomous vehicle would be impossible without the sensors. The sensors allow the vehicle to see and sense everything on the road, as well as to collect the information needed in order to drive safely. Furthermore, this information is processed and analyzed in order to build a path from point A to point B and to send the appropriate instructions to the controls of the car, such as steering, acceleration, and braking. The information collected with the sensors in the autonomous vehicles, including the actual path ahead, traffic jams, and any obstacles on the road, can also be shared between cars that are connected through M2M technology. This is called vehicle-to-vehicle communication, and it can be an incredibly helpful resource for driving automation.

The majority of today's automotive manufacturers most commonly use the following types of sensors in autonomous vehicles: cameras, radars, ultrasound, and lidars. Specific positioning of these sensors plays a vital role as the right positions of the sensors provide the autonomous vehicle maximum possible coverage of their surroundings, detect oncoming obstacles with more accuracy, and safely plan their paths. In combination with automotive software and computers, the right positioning of the sensors will allow the automation system to take over full control of the vehicle, thereby saving drivers a significant amount of time by doing tasks in much more efficient and safe ways.

Though autonomous vehicle technology appears to be developing at a continual pace, there is a phenomenal gap in resolving sensor positions optimization problem (SPOP). In brief, SPOP may be defined as a process of positioning sensors on a self-driving car that provides maximum coverage of its surrounding at minimum cost. Let us assume, there are ‘n’ different positions where one or more sensors can be positioned on the body of a car. Each such position is labeled with ‘i’=1, . . . , n. Suppose, ‘m’ different types of sensors are available, which are marked by ‘j’=1, . . . , m. Furthermore, each sensor can be oriented in ‘q’ distinct directions that are denoted by ‘q’=1, . . . , o. Let us consider the union of all the regions of interest R={1, . . . , k,} which carries k separate points from the surrounding. Each point K is further specified by the three real coordinates (xₖ, yₖ, zₖ)=rₖ. A weight (critical index) w_k belongs to [0, 1] is associated with each point that determines how important the point k is to cover. If j^{th} sensor is at i^{th} position on the car in q^{th} orientation, then it covers certain points of R. The collection of all these points, form the field of view f_{ijq} . To compute f_{ijg}, one has to use the geometry by taking sensor features (angles of view and range), position and orientation on the car, and the geography of all the regions of interest. As a result, one will get f_{ijq} as a subset of R. The calculation is required to place m different sensors at n distinct positions on a car in such a way that we get maximum possible coverage at minimum possible cost, where the priorities are given to the cover and cost.

Hence in the view of this, there is a need for a method and a system for optimizing positions of the sensors in the autonomous vehicle to get maximum possible coverage at minimum possible cost, where the priorities are given to the coverage and cost.

The above-mentioned shortcomings, disadvantages and problems are addressed herein, and which will be understood by reading and studying the following specification.

### OBJECTIVES OF THE EMBODIMENTS HEREIN

The principal object of the embodiments herein is to provide a system and a method of sensor positions optimization in an autonomous vehicle.

Another object of the embodiments herein is to provide a system and a method of sensor positions optimization in the autonomous vehicles based on quantum and quantum-inspired variational algorithm.

Yet another object of this embodiment here in is to provide a system and a method that receive weights associated with points in the regions of interest around a vehicle such as a car, possible positions of the sensors on the car, and field of view and price of each sensor to output a final sensor configuration.

Yet another object of the embodiments herein is to provide a method and a system for computing field of view and price for each of sensor specification to create a final sensor configuration.

Yet another object of the embodiments herein is to provide a method and a system for running quantum or quantum-inspired variational algorithm for various sensor configurations.

These and other objects and advantages of the present invention will become readily apparent from the following detailed description taken in conjunction with the accompanying drawings.

### SUMMARY

The following details present a simplified summary of the embodiments herein to provide a basic understanding of the several aspects of the embodiments herein. This summary is not an extensive overview of the embodiments herein. It is not intended to identify key/critical elements of the embodiments herein or to delineate the scope of the embodiments herein. Its sole purpose is to present the concepts of the embodiments herein in a simplified form as a prelude to the more detailed description that is presented later.

The other objects and advantages of the embodiments herein will become readily apparent from the following description taken in conjunction with the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications.

This Summary is provided to introduce a selection of concepts in a simplified form that is further described below in the Detailed Description. This Summary is not intended to identify key or essential features of the claimed subject matter, nor is it intended to be used as an aid in determining the scope of the claimed subject matter.

The various embodiments herein provide a method and a system for optimizing sensor positions in an autonomous vehicle based on variational quantum algorithm (VQA) and quantum-inspired variational algorithm (VQIA). The embodiments herein provide a method and a system that is configured to receive weight assigned for each point in the regions of interest around the autonomous vehicle, possible positions of the plurality of sensors on the autonomous vehicle, field of view and price of each of the plurality of sensors. The system further calculates the field of view and price of each specification based on the received weights of points in the regions of interest and possible positions of the plurality of sensors on the vehicle. The system runs quantum and quantum-inspired variational algorithm for various sensor configurations and the system completes the total number of iterations to generate a final sensor configuration.

According to one embodiment herein, a method for optimizing sensor positions in an autonomous vehicle is provided. The method comprises receiving weight assigned for each point in a region of interest, around a targeted autonomous vehicle. The weight is critical index wₖ, corresponding to each point k, in the region of interest, and is defined in the interval [0,1]. Furthermore, the region of interest represent a region or collection of points in the surrounding of the targeted autonomous vehicle and represented by set of co-ordinates in the surrounding. The method further includes receiving possible positions of a plurality of sensors on the targeted autonomous vehicle, field of view and price of each of the plurality of sensors. The field of view is the collection of points including each of the plurality of sensors at a particular position and orientation in the region of interest around the targeted autonomous vehicle. Furthermore, the method includes calculating the field of view and price of each specification, based on the received weight of points in the region of interest and possible positions of the each of the plurality of sensors on the targeted autonomous vehicle. The specification means a specific combination of the plurality of sensor type, position, and the orientation. The method further includes running a variational quantum algorithm (VQA) and quantum-inspired variational algorithm (VQIA) for each plurality of sensor configuration. The plurality of sensor configuration is a specific sensor placed at a specific position in a specific orientation. Moreover, the method includes carrying out total number of iterations using variational quantum algorithm (VQA) and quantum-inspired variational algorithm (VQIA) and obtaining the final optimized plurality of sensor configuration.

According to one embodiment herein, the method is executed through a quantum computer. The quantum computer perform calculations based on the probability of an object's state before it is measured, instead of just 1 s or 0 s. Further, the quantum computer has the potential to process exponentially more data compared to classical computers. In one embodiment, the quantum model used in the present disclosure is called a quantum circuit which is based on the quantum bit, or “qubit”.

According to one embodiment herein, the received weight determines the relative importance of the coverage of point k in the overall field of view. When the value of critical index wₖ is zero, it implies that the point k is not required in the coverage. Similarly, when the value of critical index wₖ is one, it implies that the point k is absolutely essential to cover.

According to one embodiment herein, the surrounding of the targeted autonomous vehicle is captured using the plurality of sensors and the surrounding of the targeted autonomous vehicle is focused using two separate models including front, back, right, left, top and bottom sides to collect surrounding data, to improve the region of interest prediction.

According to one embodiment herein, the field of view of the plurality of sensors in a specific position and in a specific orientation, is dependent on the sensor type, angle of view, range, position, orientation, and also on the topology of the regions of interest. The field of view computation is calibrated in a sensor hardware and provided as an input to the method for optimizing sensor positions in the autonomous vehicle.

According to one embodiment herein, the specification is a distinct point in a solution state space, and the solution state space comprises all possible combinations of n, m, and o. The ‘n’ represents the different positions where the plurality of sensors are positioned on the body of the autonomous vehicle. The ‘m’ represents the different types of the plurality of sensors, and the ‘o’ represents the different directions in which the plurality of sensors is oriented.

According to one embodiment herein, the variational quantum algorithm (VQA) is based on finding the minimum energy of a Hamiltonian, which is based on sensor position optimization problem (SPOP). The SPOP is based on positioning the plurality of sensors on the autonomous vehicle, which provides maximum coverage of its surrounding at minimum cost. Further, the Hamiltonian is the total energy of a system, including both kinetic energy and potential energy. The Hamiltonian is diagonal in the computation basis, which forms the solution space of SPOP. As per the Hamiltonian, finding the global minimum energy state is equivalent to finding an optimal solution of the SPOP state. For VQA, qubits are initialized into the starting state |x|>ᵢₙ, and then single-qubit rotations is applied to all qubits around the y-axis to obtain the parameterized quantum state-vector. Further, in VQA, the energy expectation value is minimized, and for minimization the gradient descent algorithm may be used. Furthermore, the parameters and associated key delivers the minimum energy out of all the ‘I’ iterations. In the next step, a maximum overlap is picked along the top few overlaps in terms of their magnitudes. Then, the |x>ₒᵤₜ that provides the minimum energy is calculated. In the next step, the neighborhood of |x>ₒᵤₜ is identified by moving in unit steps in the positive as well as negative directions. After the current step, the solution that delivers the minimum energy in the neighborhood of output is identified.

Moreover, the Hamiltonian H is expressed as

$$H = - a {\sum }_{k = 1}^{K} {w}_{k} {\prod }_{{f}_{k}} + b {\sum }_{l = 1}^{L} pl {\prod }_{{c}_{i}}$$

and has a direct correspondence with the objective function ε(x) for the sensor position optimization problem (SPOP) as given below, such that the first term corresponds to −awf, representing the coverage and the second term corresponds to bpx representing the cost of placing the sensor in the particular position.

$$( x ) := - a \underbrace{wf}_{cover} + b \underbrace{px}_{cost} ,$$

The minimum energy of the Hamiltonian H of SPOP corresponds to the minimum value of the objective function ε(x) and gives the optimal solution to the sensor position optimization problem SPOP.

Furthermore, in an embodiment, the sensor position optimization for autonomous vehicles as an optimization problem, seeks to find the configuration x that minimizes the objective function ε(x). The objective function ε(x) combines the terms for the coverage including effective field of view based on weights and the cost including price of placing the sensor at a particular location. Hence, the objective function is represented as

$${min}_{x} ( x ) , where$$

$$( x ) := - a \underbrace{wf}_{cover} + b \underbrace{px}_{cost}$$

where f represents the fields of view for all points in the region of interest, and p represents the price of sensor placement for all possible positions and orientations. The coefficients a and b represent the relative importance of coverage and cost respectively. Thus, by tweaking the parameters a and b, and by searching for optimal sensor configuration that minimizes ε(x), the maximum coverage with the minimum cost can be obtained.

According to one embodiment herein, the total number of iterations is a hyperparameter input to the method, and the total number of iterations includes number of times the VQA or VQIA algorithm runs to optimize the plurality of sensor configuration. Furthermore, after each iteration, better variational state is obtained, that provides lower energy and better plurality of sensor configuration. Also, in order to find the optimal solution of sensor optimization, minimization of energy expectation value of Hamiltonian <H>_{θ} over the parameter space θ is required. In the variational quantum algorithm (VQA), the energy expectation value of Hamiltonian is obtained on a quantum computer by computing the exact gradient. Similarly, in the variational quantum-inspired algorithm (VQIA), the energy expectation value of Hamiltonian is obtained on a classical computer.

According to one embodiment herein, a system for optimizing sensor positions in an autonomous vehicle is provided. The system comprises a sensor information receiving module configured to receive input, including weight assigned for each point in a region of interest, around a targeted autonomous vehicle, possible positions of a plurality of sensors, field of view and price of each of the plurality of sensors. The weight is critical index wₖ, corresponding to each point k, in the region of interest, and is defined in the interval [0,1]. Further, the region of interest represent a region or collection of points in the surrounding of the targeted autonomous vehicle and represented by set of co-ordinates in the surrounding. The field of view is the collection of points including each of the plurality of sensors at a particular position and orientation in the region of interest around the targeted autonomous vehicle. Further, the system comprises a sensor position calculation module configured to calculate the field of view and price of each specification, based on the received weight of points in the region of interest and possible positions of the each of the plurality of sensors on the targeted autonomous vehicle. The specification means a specific combination of the plurality of sensor type, position, and the orientation. The system further comprises a quantum computing module configured to run a variational quantum algorithm (VQA) and quantum-inspired variational algorithm (VQIA) for each plurality of sensor configuration. The plurality of sensor configuration is a specific sensor placed at a specific position in a specific orientation. In addition, the system comprises a sensor position optimization module configured to carry out total number of iterations using variational quantum algorithm (VQA) and quantum-inspired variational algorithm (VQIA), and to provide the final optimized plurality of sensor configuration.

According to one embodiment herein, the system is executed through a quantum computing module comprising quantum computer; and wherein the quantum computer perform calculations based on the probability of an object's state before it is measured, instead of just 1 s or 0 s; and wherein the quantum computer has the potential to process exponentially more data compared to classical computers. In one embodiment, the quantum model used in the present disclosure is called a quantum circuit which is based on the quantum bit, or “qubit”.

According to one embodiment herein, the sensor information receiving module comprising input as received weight determines the relative importance of the coverage of point k in the overall field of view. When the value of critical index wₖ is zero, it implies the point k is not required in the coverage and when the value of critical index wₖ is one, it implies that the point k is absolutely essential to cover.

According to one embodiment herein, the surrounding area of the targeted autonomous vehicle is captured using the plurality of sensors. The surrounding of the targeted autonomous vehicle is focused using two separate models including front, back, right, left, top and bottom sides to collect surrounding data, to improve the region of interest prediction.

According to one embodiment herein, the field of view of the plurality of sensors in a specific position and in a specific orientation, in the sensor information receiving module is dependent on the sensor type, angles of view, range, position, orientation, and on the topology of the regions of interest. Furthermore, the field of view computation is calibrated in a sensor hardware and provided as an input to the system.

According to one embodiment herein, the specification of the sensor position calculation module is a distinct point in a solution state space, and the solution state space comprises all possible combinations of n, m, and o. The ‘n’ represents the various positions where the plurality of sensors are positioned on the body of the autonomous vehicle, the ‘m’ represents the different types of the plurality of sensors, and the ‘o’ represents the different directions in which the plurality of sensor is oriented.

According to one embodiment herein, the variational quantum algorithm (VQA) of the quantum computing module is based on finding the minimum energy of a Hamiltonian, which is based on sensor position optimization problem (SPOP). The SPOP is based on positioning the plurality of sensors on the autonomous vehicle, which provides maximum coverage of its surrounding at minimum cost. Further, the Hamiltonian is the total energy of a system, including both kinetic energy and potential energy. The Hamiltonian is diagonal in the computation basis, which forms the solution space of SPOP. As per the Hamiltonian, finding the global minimum energy state is equivalent to finding an optimal solution of the SPOP state. For VQA, qubits are initialized into the starting state |x>ᵢₙ, and then single-qubit rotations is applied to all qubits around the y-axis to obtain the parameterized quantum state-vector. Further, in VQA, the energy expectation value is minimized, and for minimization the gradient descent algorithm may be used. Furthermore, the parameters and associated key metrics delivers the minimum energy out of all the ‘I’ iterations. In the next step, a maximum overlap is picked along the top few overlaps in terms of their magnitudes. Then, the |x>ₒᵤₜ that provides the minimum energy is calculated. In the next step, the neighborhood of |x>ₒᵤₜ is identified by moving in unit steps in the positive as well as negative directions. After the current step, the solution that delivers the minimum energy in the neighborhood of output is identified.

Moreover, the Hamiltonian H is expressed as

$$H = - a {\sum }_{k = 1}^{K} {w}_{k} {\prod }_{{f}_{k}} + b {\sum }_{l = 1}^{L} pl {\prod }_{{c}_{i}}$$

and has a direct correspondence with the objective function ε(x) for the sensor position optimization problem (SPOP) as given below, such that the first term corresponds to −awf, representing the coverage and the second term corresponds to bpx representing the cost of placing the sensor in the particular position.

$$( x ) := - a \underbrace{wf}_{cover} + b \underbrace{px}_{cost} ,$$

The minimum energy of the Hamiltonian H of SPOP corresponds to the minimum value of the objective function ε(x) and gives the optimal solution to the sensor position optimization problem SPOP.

Furthermore, in an embodiment, the sensor position optimization for autonomous vehicles as an optimization problem, seeks to find the configuration x that minimizes the objective function ε(x). The objective function ε(x) combines the terms for the coverage including effective field of view based on weights and the cost including price of placing the sensor at a particular location. Hence, the objective function is represented as

$${min}_{x} ( x ) , where$$

$$( x ) := - a \underbrace{wf}_{cover} + b \underbrace{px}_{cost}$$

where f represents the fields of view for all points in the region of interest, and p represents the price of sensor placement for all possible positions and orientations. The coefficients a and b represent the relative importance of coverage and cost respectively. Thus, by tweaking the parameters a and b, and by searching for optimal sensor configuration that minimizes ε(x), the maximum coverage with the minimum cost can be obtained.

According to one embodiment herein, the total number of iterations, carried out by the sensor position optimization module is a hyperparameter input to the system. The total number of iterations includes number of times the VQA or VQIA algorithm runs to optimize the plurality of sensor configuration, and after each iteration, better variational state is obtained, that provides lower energy and better plurality of sensor configuration. Also, in order to find the optimal solution of sensor optimization, minimization of energy expectation value of Hamiltonian <H>_{θ} over the parameter space θ is required. In the variational quantum algorithm (VQA), the energy expectation value of Hamiltonian is obtained on a quantum computer by computing the exact gradient. Similarly, in the variational quantum-inspired algorithm (VQIA), the energy expectation value of Hamiltonian is obtained on a classical computer.

The foregoing summary is illustrative only and is not intended to be in any way limiting. In addition to the illustrative aspects, embodiments, and features described above, further aspects, embodiments, and features will become apparent by reference to the drawings and the following detailed description.

These and other aspects of the embodiments herein will be better appreciated and understood when considered in conjunction with the following description and the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF THE DRAWINGS

The other objects, features and advantages will occur to those skilled in the art from the following description of the preferred embodiment and the accompanying drawings in which:

FIG. 1 illustrates a flowchart on method for optimizing sensor positions in an autonomous vehicle, according to an embodiment herein.

FIG. 2 illustrates a step-by-step method involved in optimization of sensor configuration in an autonomous vehicle, according to an embodiment herein.

FIG. 3 illustrates an exemplary high-level decomposition of a system for optimizing sensor positions in an autonomous vehicle, according to an embodiment herein.

FIG. 4A illustrates an exemplary embodiment depicting a graphical representation of performance of variational quantum algorithm for a single instance of 8 qubits, according to an embodiment herein.

FIG. 4B illustrates an exemplary embodiment depicting a graphical representation of performance of the variational quantum-inspired algorithm for a single instance of 12 qubits, according to an embodiment herein.

FIG. 5A illustrates a random initial configuration of various sensors on an autonomous vehicle, according to an embodiment herein.

FIG. 5B illustrates the final configuration of various sensors obtained from applying the sensor position optimization method, according to an embodiment herein.

Although the specific features of the present invention are shown in some drawings and not in others. This is done for convenience only as each feature may be combined with any or all of the other features in accordance with the present invention.

### DETAILED DESCRIPTION OF THE EMBODIMENTS HEREIN

In the following detailed description, reference is made to the accompanying drawings that form a part hereof, and in which the specific embodiments that may be practiced is shown by way of illustration. These embodiments are described in sufficient detail to enable those skilled in the art to practice the embodiments and it is to be understood that the logical, mechanical, and other changes may be made without departing from the scope of the embodiments. The following detailed description is therefore not to be taken in a limiting sense.

The foregoing of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments.

The accompanying drawings are used to help easily understand various technical features and it should be understood that the embodiments presented herein are not limited by the accompanying drawings. As such, the present disclosure should be construed to extend to any alterations, equivalents and substitutes in addition to those which are particularly set out in the accompanying drawings. Although the terms first, second, etc. may be used herein to describe various elements, these elements should not be limited by these terms. These terms are generally only used to distinguish one element from another.

The various embodiments herein provide a method and a system for optimizing sensor positions in an autonomous vehicle based on variational quantum algorithm (VQA) and quantum-inspired variational algorithm (VQIA). The embodiments herein provide a method and a system that is configured to receive weight assigned for each point in the regions of interest around the autonomous vehicle, possible positions of the plurality of sensors on the autonomous vehicle, field of view and price of each of the plurality of sensors. The system further calculates the field of view and price of each specification based on the received weights of points in the regions of interest and possible positions of the plurality of sensors on the vehicle. The system runs quantum and quantum-inspired variational algorithm for various sensor configurations and the system completes the total number of iterations to generate a final sensor configuration.

The term ‘autonomous vehicle’ used herein can represent a self-driving car, driverless car, or robotic car, which is a vehicle that is capable of sensing its environment and moving safely with little or no human intervention.

The term ‘region of interest’ used herein can represent a region surrounding the autonomous vehicle wherein the region of interest includes multiple points that are specified by three co-ordinates. A sensor at a particular position and orientation covers a set of such points that is called its ‘field of view’.

According to one embodiment herein, a method for optimizing sensor positions in an autonomous vehicle is provided. The method comprises receiving weight assigned for each point in a region of interest, around a targeted autonomous vehicle. The weight is critical index wₖ, corresponding to each point k, in the region of interest, and is defined in the interval [0,1]. Furthermore, the region of interest represent a region or collection of points in the surrounding of the targeted autonomous vehicle and represented by set of co-ordinates in the surrounding. The method further includes receiving possible positions of a plurality of sensors on the targeted autonomous vehicle, field of view and price of each of the plurality of sensors. The field of view is the collection of points including each of the plurality of sensors at a particular position and orientation in the region of interest around the targeted autonomous vehicle. Furthermore, the method includes calculating the field of view and price of each specification, based on the received weight of points in the region of interest and possible positions of the each of the plurality of sensors on the targeted autonomous vehicle. The specification means a specific combination of the plurality of sensor type, position, and the orientation. The method further includes running a variational quantum algorithm (VQA) and quantum-inspired variational algorithm (VQIA) for each plurality of sensor configuration. The plurality of sensor configuration is a specific sensor placed at a specific position in a specific orientation. Moreover, the method includes carrying out total number of iterations using variational quantum algorithm (VQA) and quantum-inspired variational algorithm (VQIA) and obtaining the final optimized plurality of sensor configuration.

According to one embodiment herein, the method is executed through a quantum computer. The quantum computer perform calculations based on the probability of an object's state before it is measured, instead of just 1 s or 0 s. Further, the quantum computer has the potential to process exponentially more data compared to classical computers. In one embodiment, the quantum model used in the present disclosure is called a quantum circuit which is based on the quantum bit, or “qubit”.

According to one embodiment herein, the received weight determines the relative importance of the coverage of point k in the overall field of view. When the value of critical index wₖ is zero, it implies that the point k is not required in the coverage. Similarly, when the value of critical index wₖ is one, it implies that the point k is absolutely essential to cover.

According to one embodiment herein, the surrounding of the targeted autonomous vehicle is captured using the plurality of sensors and the surrounding of the targeted autonomous vehicle is focused using two separate models including front, back, right, left, top and bottom sides to collect surrounding data, to improve the region of interest prediction.

According to one embodiment herein, the field of view of the plurality of sensors in a specific position and in a specific orientation, is dependent on the sensor type, angle of view, range, position, orientation, and also on the topology of the regions of interest. The field of view computation is calibrated in a sensor hardware and provided as an input to the method for optimizing sensor positions in the autonomous vehicle.

According to one embodiment herein, the specification is a distinct point in a solution state space, and the solution state space comprises all possible combinations of n, m, and o. The ‘n’ represents the various positions where the plurality of sensors are positioned on the body of the autonomous vehicle. The ‘m’ represents the several types of the plurality of sensors, and the ‘o’ represents the different directions in which the plurality of sensors is oriented.

According to one embodiment herein, the variational quantum algorithm (VQA) is based on finding the minimum energy of a Hamiltonian, which is based on sensor position optimization problem (SPOP). The SPOP is based on positioning the plurality of sensors on the autonomous vehicle, which provides maximum coverage of its surrounding at minimum cost. Further, the Hamiltonian is the total energy of a system, including both kinetic energy and potential energy. The Hamiltonian is diagonal in the computation basis, which forms the solution space of SPOP. As per the Hamiltonian, finding the global minimum energy state is equivalent to finding an optimal solution of the SPOP state. For VQA, qubits are initialized into the starting state |x>ᵢₙ, and then single-qubit rotations is applied to all qubits around the y-axis to obtain the parameterized quantum state-vector. Further, in VQA, the energy expectation value is minimized, and for minimization the gradient descent algorithm may be used. Furthermore, the parameters and associated ket delivers the minimum energy out of all the ‘I’ iterations. In the next step, a maximum overlap is picked along the top few overlaps in terms of their magnitudes. Then, the |x>ₒᵤₜ that provides the minimum energy is calculated. In the next step, the neighborhood of |x>ₒᵤₜ is identified by moving in unit steps in the positive as well as negative directions. After the current step, the solution that delivers the minimum energy in the neighborhood of output is identified.

Moreover, the Hamiltonian H is expressed as

$$H = - a {\sum }_{k = 1}^{K} {w}_{k} {\prod }_{{f}_{k}} + b {\sum }_{l = 1}^{L} pl {\prod }_{{c}_{i}}$$

and has a direct correspondence with the objective function ε(x) for the sensor position optimization problem (SPOP) as given below, such that the first term corresponds to awf, representing the coverage and the second term corresponds to bpx representing the cost of placing the sensor in the particular position.

$$( x ) := - a \underbrace{wf}_{cover} + b \underbrace{px}_{cost} ,$$

The minimum energy of the Hamiltonian H of SPOP corresponds to the minimum value of the objective function ε(x) and gives the optimal solution to the sensor position optimization problem SPOP.

Furthermore, in an embodiment, the sensor position optimization for autonomous vehicles as an optimization problem, seeks to find the configuration x that minimizes the objective function ε(x). The objective function ε(x) combines the terms for the coverage including effective field of view based on weights and the cost including price of placing the sensor at a particular location. Hence, the objective function is represented as

$${min}_{x} ( x ) , where$$

$$( x ) := - a \underbrace{wf}_{cover} + b \underbrace{px}_{cost}$$

where f represents the fields of view for all points in the region of interest, and p represents the price of sensor placement for all possible positions and orientations. The coefficients a and b represent the relative importance of coverage and cost respectively. Thus, by tweaking the parameters a and b, and by searching for optimal sensor configuration that minimizes ε(x), the maximum coverage with the minimum cost can be obtained.

According to one embodiment herein, the total number of iterations is a hyperparameter input to the method, and the total number of iterations includes number of times the VQA or VQIA algorithm runs to optimize the plurality of sensor configuration. Furthermore, after each iteration, better variational state is obtained, that provides lower energy and better plurality of sensor configuration. Also, in order to find the optimal solution of sensor optimization, minimization of energy expectation value of Hamiltonian <H>_{θ} over the parameter space θ is required. In the variational quantum algorithm (VQA), the energy expectation value of Hamiltonian is obtained on a quantum computer by computing the exact gradient. Similarly, in the variational quantum-inspired algorithm (VQIA), the energy expectation value of Hamiltonian is obtained on a classical computer.

According to one embodiment herein, a system for optimizing sensor positions in an autonomous vehicle is provided. The system comprises a sensor information receiving module configured to receive input, including weight assigned for each point in a region of interest, around a targeted autonomous vehicle, possible positions of a plurality of sensors, field of view and price of each of the plurality of sensors. The weight is critical index wₖ, corresponding to each point k, in the region of interest, and is defined in the interval [0,1]. Further, the region of interest represent a region or collection of points in the surrounding of the targeted autonomous vehicle and represented by set of co-ordinates in the surrounding. The field of view is the collection of points including each of the plurality of sensors at a particular position and orientation in the region of interest around the targeted autonomous vehicle. Further, the system comprises a sensor position calculation module configured to calculate the field of view and price of each specification, based on the received weight of points in the region of interest and possible positions of the each of the plurality of sensors on the targeted autonomous vehicle. The specification means a specific combination of the plurality of sensor type, position, and the orientation. The system further comprises a quantum computing module configured to run a variational quantum algorithm (VQA) and quantum-inspired variational algorithm (VQIA) for each plurality of sensor configuration. The plurality of sensor configuration is a specific sensor placed at a specific position in a specific orientation. In addition, the system comprises a sensor position optimization module configured to carry out total number of iterations using variational quantum algorithm (VQA) and quantum-inspired variational algorithm (VQIA), and to provide the final optimized plurality of sensor configuration.

According to one embodiment herein, the system is executed through a quantum computing module comprising quantum computer; and wherein the quantum computer perform calculations based on the probability of an object's state before it is measured, instead of just 1 s or 0 s; and wherein the quantum computer has the potential to process exponentially more data compared to classical computers. In one embodiment, the quantum model used in the present disclosure is called a quantum circuit which is based on the quantum bit, or “qubit”.

According to one embodiment herein, the sensor information receiving module comprising input as received weight determines the relative importance of the coverage of point k in the overall field of view. When the value of critical index wₖ is zero, it implies the point k is not required in the coverage and when the value of critical index wₖ is one, it implies that the point k is absolutely essential to cover.

According to one embodiment herein, the surrounding area of the targeted autonomous vehicle is captured using the plurality of sensors. The surrounding of the targeted autonomous vehicle is focused using two separate models including front, back, right, left, top and bottom sides to collect surrounding data, to improve the region of interest prediction.

According to one embodiment herein, the field of view of the plurality of sensors in a specific position and in a specific orientation, in the sensor information receiving module is dependent on the sensor type, angles of view, range, position, orientation, and on the topology of the regions of interest. Furthermore, the field of view computation is calibrated in a sensor hardware and provided as an input to the system.

According to one embodiment herein, the specification of the sensor position calculation module is a distinct point in a solution state space, and the solution state space comprises all possible combinations of n, m, and o. The ‘n’ represents the various positions where the plurality of sensors are positioned on the body of the autonomous vehicle, the ‘m’ represents the different types of the plurality of sensors, and the ‘o’ represents the different directions in which the plurality of sensor is oriented.

According to one embodiment herein, the variational quantum algorithm (VQA) of the quantum computing module is based on finding the minimum energy of a Hamiltonian, which is based on sensor position optimization problem (SPOP). The SPOP is based on positioning the plurality of sensors on the autonomous vehicle, which provides maximum coverage of its surrounding at minimum cost. Further, the Hamiltonian is the total energy of a system, including both kinetic energy and potential energy. The Hamiltonian is diagonal in the computation basis, which forms the solution space of SPOP. As per the Hamiltonian, finding the global minimum energy state is equivalent to finding an optimal solution of the SPOP state. For VQA, qubits are initialized into the starting state |x>ᵢₙ, and then single-qubit rotations is applied to all qubits around the y-axis to obtain the parameterized quantum state-vector. Further, in VQA, the energy expectation value is minimized, and for minimization the gradient descent algorithm may be used. Furthermore, the parameters and associated ket delivers the minimum energy out of all the ‘I’ iterations. In the next step, a maximum overlap is picked along the top few overlaps in terms of their magnitudes. Then, the |x>ₒᵤₜ that provides the minimum energy is calculated. In the next step, the neighborhood of |x>ₒᵤₜ is identified by moving in unit steps in the positive as well as negative directions. After the current step, the solution that delivers the minimum energy in the neighborhood of output is identified.

Moreover, the Hamiltonian H is expressed as

$$H = - a {\sum }_{k = 1}^{K} {w}_{k} {\prod }_{{f}_{k}} + b {\sum }_{l = 1}^{L} pl {\prod }_{{c}_{i}}$$

and has a direct correspondence with the objective function ε(x) for the sensor position optimization problem (SPOP) as given below, such that the first term corresponds to awf, representing the coverage and the second term corresponds to bpx representing the cost of placing the sensor in the particular position.

$$( x ) := - a \underbrace{wf}_{cover} + b \underbrace{px}_{cost} ,$$

The minimum energy of the Hamiltonian H of SPOP corresponds to the minimum value of the objective function E(x) and gives the optimal solution to the sensor position optimization problem SPOP.

Furthermore, in an embodiment, the sensor position optimization for autonomous vehicles as an optimization problem, seeks to find the configuration x that minimizes the objective function ε(x). The objective function ε(x) combines the terms for the coverage including effective field of view based on weights and the cost including price of placing the sensor at a particular location. Hence, the objective function is represented as

$${min}_{x} ( x ) , where$$

$$( x ) := - a \underbrace{wf}_{cover} + b \underbrace{px}_{cost}$$

where f represents the fields of view for all points in the region of interest, and p represents the price of sensor placement for all possible positions and orientations. The coefficients a and b represent the relative importance of coverage and cost respectively. Thus, by tweaking the parameters a and b, and by searching for optimal sensor configuration that minimizes ε(x), the maximum coverage with the minimum cost can be obtained.

According to one embodiment herein, the total number of iterations, carried out by the sensor position optimization module is a hyperparameter input to the system. The total number of iterations includes number of times the VQA or VQIA algorithm runs to optimize the plurality of sensor configuration, and after each iteration, better variational state is obtained, that provides lower energy and better plurality of sensor configuration. Also, in order to find the optimal solution of sensor optimization, minimization of energy expectation value of Hamiltonian <H>_{θ} over the parameter space θ is required. In the variational quantum algorithm (VQA), the energy expectation value of Hamiltonian is obtained on a quantum computer by computing the exact gradient. Similarly, in the variational quantum-inspired algorithm (VQIA), the energy expectation value of Hamiltonian is obtained on a classical computer.

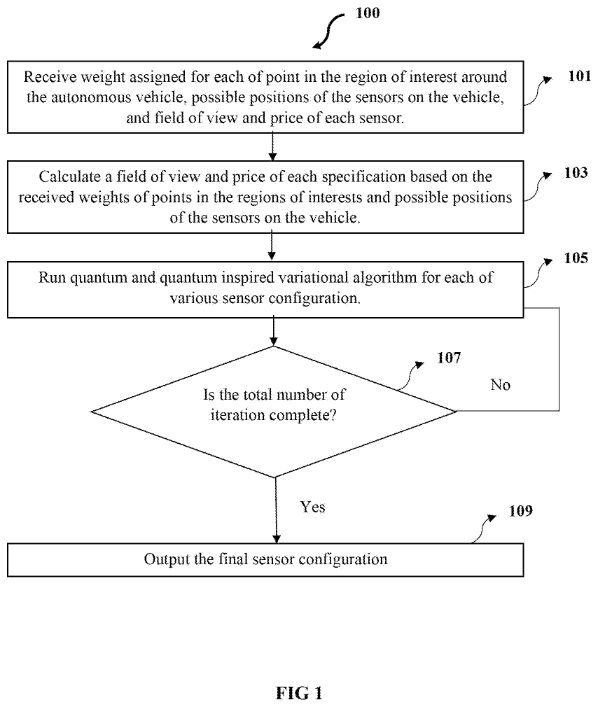

FIG. 1 illustrates a flowchart on method for optimizing sensor positions in an autonomous vehicle, according to an embodiment herein. The method 100 comprises receiving weight assigned for each point in a region of interest, around a targeted autonomous vehicle at step 101. The weight is critical index wₖ, corresponding to each point k, in the region of interest, and is defined in the interval [0,1]. Furthermore, the region of interest represent a region or collection of points in the surrounding of the targeted autonomous vehicle and represented by set of co-ordinates in the surrounding. The method 100 further includes receiving possible positions of a plurality of sensors on the targeted autonomous vehicle, field of view and price of each of the plurality of sensors at step 101. The field of view is the collection of points including each of the plurality of sensors at a particular position and orientation in the region of interest around the targeted autonomous vehicle. Furthermore, the method 100 includes calculating the field of view and price of each specification, based on the received weight of points in the region of interest and possible positions of the each of the plurality of sensors on the targeted autonomous vehicle at step 103. The specification means a specific combination of the plurality of sensor type, position, and the orientation. The method 100 further includes running a variational quantum algorithm (VQA) and quantum-inspired variational algorithm (VQIA) for each plurality of sensor configuration at step 105. The plurality of sensor configuration is a specific sensor placed at a specific position in a specific orientation. Moreover, the method 100 includes carrying out total number of iterations using variational quantum algorithm (VQA) and quantum-inspired variational algorithm (VQIA) at step 107 and obtaining the final optimized plurality of sensor configuration 109.

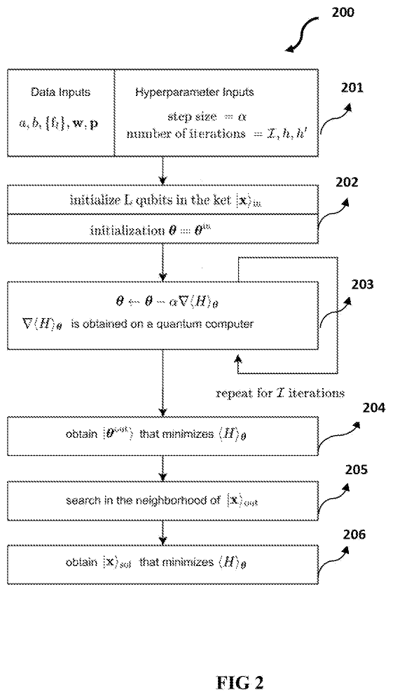

FIG. 2 illustrates a step-by-step method involved in optimization of sensor configuration in an autonomous vehicle, according to an embodiment herein. In the variational quantum algorithm (VQA) is based on finding the minimum energy of a Hamiltonian that is based on the SPOP. After each iteration, we get a better variational state that provides lower energy, and thus gives a better sensor configuration. The Hamiltonian is diagonal in the computation basis, which forms the solution space of SPOP. As per the Hamiltonian, finding the global minimum energy state is equivalent to finding an optimal solution of the SPOP state. Firstly, hyperparameter inputs are obtained at step 201. Further, for VQA, qubits are initialized into the starting state |x>ᵢₙ at step 202, and then single-qubit rotations is applied to all qubits around the y-axis to obtain the parameterized quantum state-vector. In VQA, the energy expectation value is minimized. Further, for minimization the gradient descent algorithm may be used. Then, the parameters and associated ket delivers the minimum energy out of all the ‘I’ iterations at step 203. In the next step, a maximum overlap is picked along the top few overlaps in terms of their magnitudes at step 204. Then, the |x>ₒᵤₜ that provides the minimum energy is calculated at step 205. In the next step, the neighborhood of |x>ₒᵤₜ is identified by moving in unit steps in the positive as well as negative directions. After the current step, the solution that delivers the minimum energy in the neighborhood of output is identified at step 206.

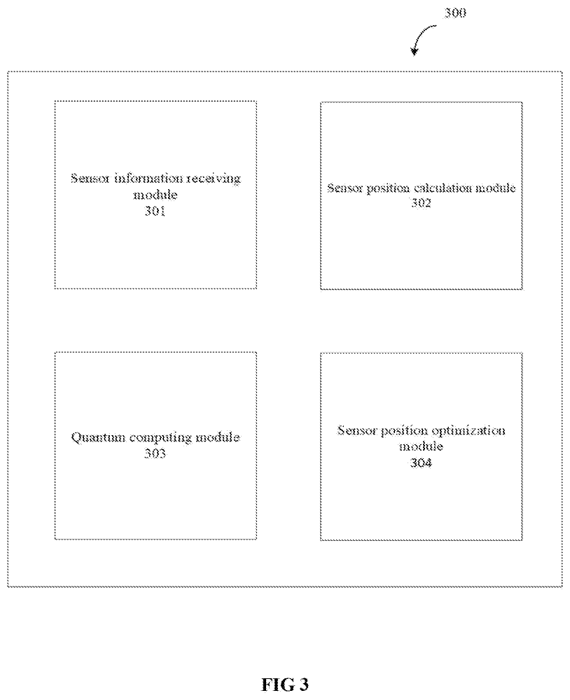

FIG. 3 illustrates an exemplary high-level decomposition of a system for optimizing sensor positions in an autonomous vehicle, according to an embodiment herein. In an embodiment, the system 300 comprises a sensor information receiving module 301 configured to receive input, including weight assigned for each point in a region of interest, around a targeted autonomous vehicle, possible positions of a plurality of sensors, field of view and price of each of the plurality of sensors. The weight is critical index wₖ, corresponding to each point k, in the region of interest, and is defined in the interval [0,1]. Further, the region of interest represent a region or collection of points in the surrounding of the targeted autonomous vehicle and represented by set of co-ordinates in the surrounding. The field of view is the collection of points including each of the plurality of sensors at a particular position and orientation in the region of interest around the targeted autonomous vehicle. Further, the system 300 comprises a sensor position calculation module 302 configured to calculate the field of view and price of each specification, based on the received weight of points in the region of interest and possible positions of the each of the plurality of sensors on the targeted autonomous vehicle. The specification means a specific combination of the plurality of sensor type, position, and the orientation. The system 300 further comprises a quantum computing module 303 configured to run a variational quantum algorithm (VQA) and quantum-inspired variational algorithm (VQIA) for each plurality of sensor configuration. The plurality of sensor configuration is a specific sensor placed at a specific position in a specific orientation. In addition, the system 300 comprises a sensor position optimization module 304 configured to carry out total number of iterations using variational quantum algorithm (VQA) and quantum-inspired variational algorithm (VQIA), and to provide the final optimized plurality of sensor configuration.

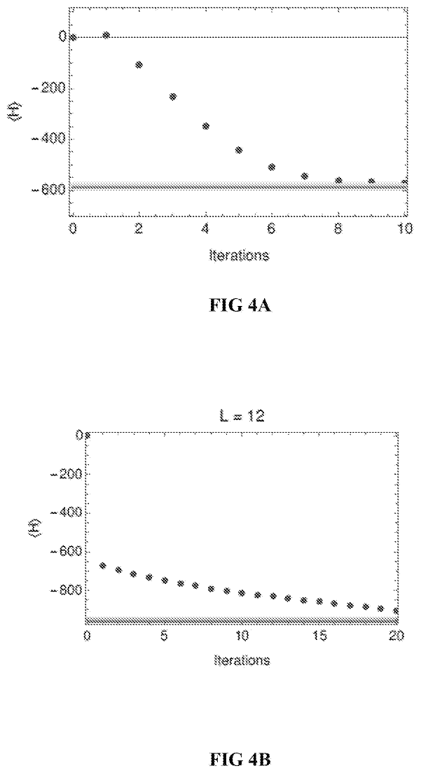

In one embodiment, the performance of the VQA depends on the chosen starting point such as |x>ᵢₙ. The algorithm is executed several times by starting from different |x>ᵢₙ, and then by selecting the best |x>ₛₒₗ. In one example, the performance of the VQA is calculated for a single instance for L=8 qubits. In this instance, the global minimum is achieved. Over time, the average performance of our algorithms is investigated with respect to the number of positions, such as ‘K’ points and the number of qubits L. A graphical representation current example of the VQA is presented in FIG. 4A.

FIG. 4A illustrates an exemplary embodiment depicting a graphical representation of performance of variational quantum algorithm for a single instance of 8 qubits, according to an embodiment herein. The sequence of blue dots is the result of plotting the acquired minimum energy (Hamiltonian expectation value <H>) versus iterations plot obtained from a classical simulation of VQA, where the points on the region of interest are K=1000; with ‘n=4’ different positions where one or more sensors are positioned on the body of the vehicle; with ‘m=2’ different types of sensors and each sensor can be oriented in ‘o=1’ distinct directions. The red line shows the global minimum acquired from the exact diagonalization of Hamiltonian. The green line represents the minimum obtained from VQA after I=10 iterations. The over-lapping of green and red lines reveals that the global minimum in this example is achieved, wherein the number of qubits L=8. Further, with respect to FIG. 1, at 109, the method 100 is configured to output the final sensor configuration after the completion of the number of iterations.

According to one embodiment herein, the total number of iterations are carried out based on variational quantum-inspired algorithm (VQIA). In one embodiment, the performance of the VQIA is represented in FIG. 4B. The FIG. 4B illustrates an exemplary embodiment depicting a graphical representation of performance of the variational quantum-inspired algorithm for a single instance of L=12 qubits. The sequence of blue dots is the result of plotting the energy (Hamiltonian expectation value <H>) versus iterations plot obtained from the VQIA, where the points on the region of interest are K=1000; with ‘n=4’ different positions where one or more sensors are positioned on the body of the vehicle; with ‘m=3’ different types of sensors and each sensor can be oriented in ‘o=1’ distinct directions. The red line shows the global minimum acquired from the exact diagonalization of Hamiltonian. The green line represents the minimum obtained from VQIA after I=20 iterations. The over-lapping of green and red lines reveals that the global minimum in this example is achieved, wherein the number of qubits L=12.

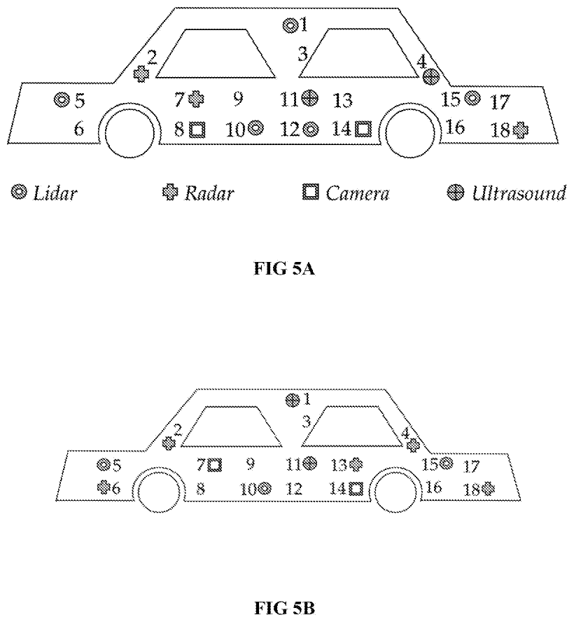

FIG. 5A illustrates a random initial configuration of various sensors on an autonomous vehicle, according to an embodiment herein. The autonomous vehicle contains 18 possible locations to place 4 different kinds of sensors—LIDAR, RADAR, Camera, Ultrasound. The vehicle sensor configuration is provided in Table 1 as illustrated below:

TABLE 1

| Position | Sensor |
|---|---|
| 1 | LIDAR |
| 2 | RADAR |
| 3 | No sensor |
| 4 | Ultrasound |
| 5 | LIDAR |
| 6 | No sensor |
| 7 | RADAR |
| 8 | Camera |
| 9 | No sensor |
| 10 | LIDAR |
| 11 | Ultrasound |
| 12 | LIDAR |
| 13 | No sensor |
| 14 | Camera |
| 15 | LIDAR |
| 16 | No sensor |
| 17 | No sensor |
| 18 | RADAR |

FIG. 5B illustrates the final configuration of various sensors obtained from applying the sensor position optimization method, according to an embodiment herein. The vehicle sensor configuration after optimization in provided in Table 2.

TABLE 2

| Position | Sensor |
|---|---|
| 1 | Ultrasound |
| 2 | RADAR |
| 3 | No sensor |
| 4 | RADAR |
| 5 | LIDAR |
| 6 | RADAR |
| 7 | Camera |
| 8 | No sensor |
| 9 | No sensor |
| 10 | LIDAR |
| 11 | Ultrasound |
| 12 | No sensor |
| 13 | RADAR |
| 14 | Camera |
| 15 | LIDAR |
| 16 | No sensor |
| 17 | No sensor |
| 18 | RADAR |

It is also to be understood that various arrangements may be devised that, although not explicitly described or shown herein, embody the principles of the present disclosure. Moreover, all statements herein reciting principles, aspects, and embodiments of the present disclosure, as well as specific examples, are intended to encompass equivalents thereof.

While the disclosure is susceptible to various modifications and alternative forms, specific embodiment thereof has been shown by way of example in the drawings and will be described in detail above. It should be understood, however that it is not intended to limit the disclosure to the forms disclosed, but on the contrary, the disclosure is to cover all modifications, equivalents, and alternatives falling within the scope of the disclosure.

The embodiments herein disclose a system and method for optimizing sensor positions in an autonomous vehicle to address sensor position optimization problem. The embodiment herein provides a sensor optimization solution for the autonomous vehicle to get maximum possible coverage at minimum possible cost, where the priorities are given to the coverage and cost. As sensor position optimization is a combinatorically hard problem and lies in the NP-Hard category (non-deterministic polynomial-time hardness), it is hard to solve using exact, deterministic classical methods. In such scenarios, high-quality solutions cannot be obtained beyond a few variables within reasonable times. While there are approximate classical methods running on classical computing infrastructure, these methods are limited to a few hundred variables. Even approximate calculations leads to sub-optimal solutions and the system cannot scale to realistic scenarios that are required in autonomous vehicle manufacturing-scale environments. Hence, the embodiment herein presents a system and method for performing the sensor positioning optimization task on a quantum computer. The method can scale to millions of decision variables with scalable quantum devices and obtain high-quality solutions that are very close to the global minimum. The key metrics for performance advantage includes solution quality, time to solution and scalability or the number of decision variables.

Although the embodiments herein are described with various specific embodiments, it will be obvious for a person skilled in the art to practice the embodiments herein with modifications.

The foregoing description of the specific embodiments will so fully reveal the general nature of the embodiments herein that others can, by applying current knowledge, readily modify and/or adapt for various applications such as specific embodiments without departing from the generic concept, and, therefore, such adaptations and modifications should and are intended to be comprehended within the meaning and range of equivalents of the disclosed embodiments.

It is to be understood that the phrases or terminology employed herein is for the purpose of description and not of limitation. Therefore, while the embodiments herein have been described in terms of preferred embodiments, those skilled in the art will recognize that the embodiments herein can be practiced with modifications. However, all such modifications are deemed to be within the scope of the claims.

What is claimed is:

1. A method (100) for optimizing sensor positions in an autonomous vehicle comprising the steps of:
a. receiving weight assigned for each point in a region of interest, around a targeted autonomous vehicle (101); and wherein the weight is critical index wₖ, corresponding to each point k, in the region of interest, and is defined in the interval [0,1]; and wherein the region of interest represent a region or collection of points in the surrounding of the targeted autonomous vehicle, and represented by set of co-ordinates in the surrounding;
b. receiving possible positions of a plurality of sensors on the targeted autonomous vehicle, field of view and price of each of the plurality of sensors (101); and wherein the field of view is the collection of points including each of the plurality of sensors at a particular position and orientation in the region of interest around the targeted autonomous vehicle;
c. calculating the field of view and price of each specification, based on the received weight of points in the region of interest and possible positions of the each of the plurality of sensors on the targeted autonomous vehicle (103); and wherein the specification means a specific combination of the plurality of sensor type, position, and the orientation;
d. running a variational quantum algorithm (VQA) and quantum-inspired variational algorithm (VQIA) for each plurality of sensor configuration (105); and wherein the plurality of sensor configuration is a specific sensor placed at a specific position in a specific orientation;
e. carrying out total number of iterations using variational quantum algorithm (VQA) and quantum-inspired variational algorithm (VQIA) (107); and
f obtaining the final optimized plurality of sensor configuration (109);

2. The method (100) according to claim 1, wherein the method (100) is executed through a quantum computer; and wherein the quantum computer performs calculations based on the probability of an object's state before it is measured, instead of just 1 s or 0 s; and wherein the quantum computer has the potential to process exponentially more data compared to classical computers.

3. The method (100) according to claim 1, wherein the received weight determines the relative importance of the coverage of point k in the overall field of view; and wherein when the value of critical index wₖ is zero, implies the point k is not required in the coverage; and wherein when the value of critical index wₖ is one, implies that the point k is absolutely essential to cover.

4. The method (100) according to claim 1, wherein the surrounding of the targeted autonomous vehicle is captured using the plurality of sensors; and wherein the surrounding of the targeted autonomous vehicle is focused using two separate models including front, back, right, left, top and bottom sides to collect surrounding data, to improve the region of interest prediction.

5. The method (100) according to claim 1, wherein the field of view of the plurality of sensors in a specific position and in a specific orientation, is dependent on the sensor type, angle of view, range, position, orientation, and also on the topology of the regions of interest; and wherein the field of view computation is calibrated in a sensor hardware, and provided as an input to the method (100).

6. The method (100) according to claim 1, wherein the specification is a distinct point in a solution state space; and wherein the solution state space comprises all possible combinations of n, m, and o; wherein the n represents the different positions where the plurality of sensors are positioned on the body of the autonomous vehicle; and wherein the m represents the different types of the plurality of sensors, and wherein the o represents the different directions in which the plurality of sensor is oriented.

7. The method (100) according to claim 1, wherein the variational quantum algorithm (VQA) is based on finding the minimum energy of a Hamiltonian, which is based on sensor position optimization problem (SPOP); and wherein the SPOP is positioning the plurality of sensors on the autonomous vehicle, that provides maximum coverage of its surrounding at minimum cost; and wherein the Hamiltonian is the total energy of a system, including both kinetic energy and potential energy.

8. The method (100) according to claim 1, wherein the total number of iterations is a hyperparameter input to the method (100); and wherein the total number of iterations includes number of times the VQA or VQIA algorithm runs to optimize the plurality of sensor configuration; and wherein after each iteration, better variational state is obtained, that provides lower energy and better plurality of sensor configuration.

9. A system (300) for optimizing sensor positions in an autonomous vehicle comprising:
a. a sensor information receiving module (301) configured to receive input, including weight assigned for each point in a region of interest, around a targeted autonomous vehicle, possible positions of a plurality of sensors, field of view and price of each of the plurality of sensors; and wherein the weight is critical index wₖ, corresponding to each point k, in the region of interest, and is defined in the interval [0,1]; and wherein the region of interest represent a region or collection of points in the surrounding of the targeted autonomous vehicle, and represented by set of co-ordinates in the surrounding; and wherein the field of view is the collection of points including each of the plurality of sensors at a particular position and orientation in the region of interest around the targeted autonomous vehicle;
b. a sensor position calculation module (302) configured to calculate the field of view and price of each specification, based on the received weight of points in the region of interest and possible positions of the each of the plurality of sensors on the targeted autonomous vehicle; and wherein the specification means a specific combination of the plurality of sensor type, position, and the orientation;
c. a quantum computing module (303) configured to run a variational quantum algorithm (VQA) and quantum-inspired variational algorithm (VQIA) for each plurality of sensor configuration; and wherein the plurality of sensor configuration is a specific sensor placed at a specific position in a specific orientation; and
d. a sensor position optimization module (304) configured to carry out total number of iterations using variational quantum algorithm (VQA) and quantum-inspired variational algorithm (VQIA), and to provide the final optimized plurality of sensor configuration.

10. The system (300) according to claim 9, wherein the system (300) is executed through a quantum computing module comprising quantum computer; and wherein the quantum computer perform calculations based on the probability of an object's state before it is measured, instead of just 1 s or 0 s; and wherein the quantum computer has the potential to process exponentially more data compared to classical computers.

11. The system (300) according to claim 9, wherein the sensor information receiving module comprising input as received weight determines the relative importance of the coverage of point kin the overall field of view; and wherein when the value of critical index wₖ is zero, implies the point k is not required in the coverage; and wherein when the value of critical index wₖ is one, implies that the point k is absolutely essential to cover.

12. The system (300) according to claim 9, wherein the surrounding of the targeted autonomous vehicle is captured using the plurality of sensors; and wherein the surrounding of the targeted autonomous vehicle is focused using two separate models including front, back, right, left, top and bottom sides to collect surrounding data, to improve the region of interest prediction.

13. The system (300) according to claim 9, wherein the field of view of the plurality of sensors in a specific position and in a specific orientation, in the sensor information receiving module is dependent on the sensor type, angles of view, range, position, orientation, and also on the topology of the regions of interest; and wherein the field of view computation is calibrated in a sensor hardware, and provided as an input to the system (300).

14. The system (300) according to claim 9, wherein the specification of the sensor position calculation module is a distinct point in a solution state space; and wherein the solution state space comprises all possible combinations of n, m, and o; wherein the n represents the different positions where the plurality of sensors are positioned on the body of the autonomous vehicle; and wherein the m represents the different types of the plurality of sensors, and wherein the o represents the different directions in which the plurality of sensor is oriented.

15. The system (300) according to claim 9, wherein the variational quantum algorithm (VQA) of the quantum computing module is based on finding the minimum energy of a Hamiltonian, which is based on sensor position optimization problem (SPOP); and wherein the SPOP is positioning the plurality of sensors on the autonomous vehicle, that provides maximum coverage of its surrounding at minimum cost; and wherein the Hamiltonian is the total energy of a system, including both kinetic energy and potential energy.

16. The system (300) according to claim 9, wherein the total number of iterations, carried out by the sensor position optimization module is a hyperparameter input to the system (300); and wherein the total number of iterations includes number of times the VQA or VQIA algorithm runs to optimize the plurality of sensor configuration; and wherein after each iteration, better variational state is obtained, that provides lower energy and better plurality of sensor configuration.
